(19) United States
(12) Patent Application Publication
(10) Pub. No.: US 2008/0179734 A1
(43) Pub. Date: Jul. 31, 2008

(54) STACKED PACKAGE, METHOD OF MANUFACTURING THE SAME, AND MEMORY CARD HAVING THE STACKED PACKAGE

(75) Inventors: Yong-Chai KWON, Gyeonggi-do (KR); Dong-Ho LEE, Gyeonggi-do (KR); Sun-Won KANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/018,743

(22) Filed: Jan. 23, 2008

(30) Foreign Application Priority Data
Jan. 25, 2007 (KR) 2007-007692

(51) Int. Cl. H01L 23/538; H01L 21/52

(52) U.S. Cl. 257/691; 438/109; 257/E23.169; 257/E21.5

(57) ABSTRACT

A stacked package includes a printed circuit board (PCB), a plurality of semiconductor chips, plugs and a controller. The semiconductor chips are sequentially stacked on the PCB. The plugs electrically connect each of the semiconductor chips to the PCB. The controller is disposed in any one of the semiconductor chips. The controller is electrically coupled to the plugs. Thus, the controller may be built in the semiconductor chip by a separate process so that a mechanical impact generated in a process for bonding the controller is not applied to the semiconductor chips. Further, a mechanical impact applied to the controller, which is generated in a process for forming a protection member, may be reduced.

### CROSS-REFERENCE TO RELATED APPLICATION

This application claims priority under 35 USC § 119 to Korean Patent Application No. 2007-7692 filed on Jan. 25, 2007, the contents of which are herein incorporated by reference in their entirety.

### BACKGROUND

1. Technical Field

Example embodiments of the present invention relate to a stacked package, a method of manufacturing the same, and a memory card having the stacked package. More particularly, example embodiments of the present invention relate to a stacked package for a memory card that includes a plurality of stacked semiconductor chips, a method of manufacturing the stacked package, and a memory card having the stacked package.

2. Description of the Related Art

Generally, various semiconductor processes may be carried out on a semiconductor substrate to form a plurality of semiconductor chips. To mount the semiconductor chips on a motherboard, a packaging process may be performed on the semiconductor substrate to form a semiconductor package.

Further, in an effort to increase the storage capacity of the semiconductor package, a stacked semiconductor package including a plurality of stacked semiconductor chips has been widely researched. Particularly, the stacked semiconductor package has been extensively researched for use in a memory card. The stacked semiconductor package for the memory card may include a printed circuit board (PCB), a plurality of semiconductor chips stacked on the PCB and electrically connected to each other, and a controller for controlling operations of the semiconductor chips. Conventional examples of the stacked semiconductor package for the memory card are disclosed in U.S. Pat. Nos. 6,538,331 and 6,624,506, Korean Patent No. 603932, etc.

However, in the conventional stacked semiconductor packages for the memory card, the controller may be mounted on an uppermost semiconductor chip among the semiconductor chips. Thus, when the controller is mounted on the uppermost semiconductor chip, a strong mechanical force may be applied to the semiconductor chips possibly damaging the semiconductor chips.

Further, while the controller and the semiconductor chips are being molded by a protection member, a strong mechanical force may be applied to the controller, possibly damaging the controller.

The present invention addresses these and other disadvantages of the conventional art.

### SUMMARY

Example embodiments of the present invention provide a stacked package that is capable of buffering mechanical impacts applied to a controller and semiconductor chips. Example embodiments of the present invention also provide a method of manufacturing the above-mentioned stacked package. Example embodiments of the present invention still also provide a memory card having the above-mentioned stacked package.

A stacked package in accordance with one aspect of the present invention includes a printed circuit board (PCB), a plurality of semiconductor chips, plugs and a controller. The semiconductor chips are sequentially stacked on the PCB. The plugs electrically connect each of the semiconductor chips to the PCB. The controller is built in any one of the semiconductor chips. Further, the controller is electrically coupled to the plugs.

According to some embodiments of the present invention, the controller may be built in the semiconductor chip by a separate process so that a mechanical impact generated in a process for bonding the controller may not be applied to the semiconductor chips. Further, a mechanical impact generated in a process for forming the protection member may not be applied to the controller.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross-sectional view illustrating a stacked package in accordance with example embodiments of the present invention;

FIG. 2 is an enlarged cross-sectional view of a portion II of FIG. 1;

FIGS. 3 to 11 are cross-sectional views illustrating a method of manufacturing a stacked package in accordance with example embodiments of the present invention;

FIG. 12 is a cross-sectional view illustrating a stacked package in accordance with example embodiments of the present invention;

FIG. 13 is a cross-sectional view illustrating a stacked package in accordance with example embodiments of the present invention;

FIG. 14 is a cross-sectional view illustrating a stacked package in accordance with example embodiments of the present invention;

FIGS. 15 to 22 are cross-sectional views illustrating a method of manufacturing a stacked package in accordance with example embodiments of the present invention;

FIG. 23 is a cross-sectional view illustrating a memory card in accordance with example embodiments of the present invention.

### DETAILED DESCRIPTION

The present invention is described more fully hereinafter with reference to the accompanying drawings, in which example embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

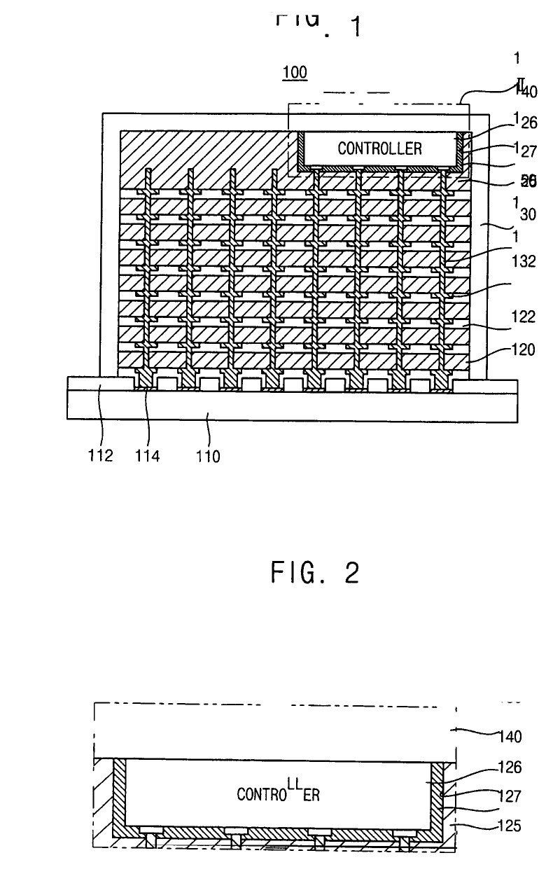

FIG. 1 is a cross-sectional view illustrating a stacked package in accordance with example embodiments of the present invention, and FIG. 2 is an enlarged cross-sectional view illustrating a portion II of FIG. 1.

Referring to FIGS. 1 and 2, a stacked package 100 of example embodiments includes a printed circuit board (PCB) 110, a plurality of semiconductor chips 120, plugs 130, a controller 140 and a protection member 150. In an example embodiment, the stacked package 100 may be used for a memory card. The stacked package 100 may also be used for other applications.

The PCB 110 includes a plurality of electrode pads 114. The electrode pads 114 are arranged on an upper face of the PCB 110. An insulation layer pattern 112 is formed on the PCB to expose the electrode pads 114. The insulation layer pattern 112 may include a photo solder resist (PSR) layer.

The semiconductor chips 120 are sequentially stacked on the PCB 110. An adhesive layer 122 is interposed between a lowermost semiconductor chip 120 and the PCB 110, and between the semiconductor chips 120.

Further, via holes are vertically formed through the semiconductor chips 120. The via holes are filled with the plugs 130. Each of the plugs 130 has a head portion 132 protruded through a lower face of the via hole. Each of the head portions 132 makes contact with an upper end of an adjacent plug 130 so that the plugs 130 are electrically coupled to each other. The plugs 130 are formed at a scribe lane of each of the semiconductor chips 120. The plugs 130 are electrically coupled to a bonding pad (not shown) of the semiconductor chips 120.

An uppermost semiconductor chip 125 among the stacked semiconductor chips 120 has a cavity 126. In an example embodiment, the cavity 126 may be formed at a surface portion of the uppermost semiconductor chip 125. Further, the cavity 126 may have a rectangular cross-sectional shape. To provide the cavity 126 with a sufficient depth, the uppermost semiconductor chip 125 may have a thickness greater than that of other semiconductor chips 120.

The controller 140 for controlling operations of the semiconductor chips 120 is received in the cavity 126. An upper end of the plug 130 in the uppermost semiconductor chip 125 is exposed through a bottom face of the cavity 126. In an example embodiment, an adhesive layer 127 may be formed on an inner face of the cavity 126. The plug 130 is exposed through the adhesive layer 127. Therefore, since the controller 140 is received in the cavity 126 of the uppermost semiconductor chip 125, a mechanical shock applied to the semiconductor chips 120, which may be generated in a process for bonding the controller 140, may be buffered. Further, a mechanical shock applied to the controller 140, which may be generated in a process for forming the protection member 150, may be reduced.

In example embodiments, to prevent the controller 140 from being protruded from an upper face of the uppermost semiconductor chip 125, the cavity 126 may have a depth substantially equal to or greater than a thickness of the controller 140.

The protection member 150 is formed on side faces and the upper face of the semiconductor chips 120 and an upper face of the insulation layer pattern 112 so as to substantially surround the semiconductor chips 120 and the controller 140. The protection member 150 protects the semiconductor chips 120 and the controller 140 from external shocks. In this example embodiment, an example of the protection member 150 may include an insulation material such as epoxy resin.

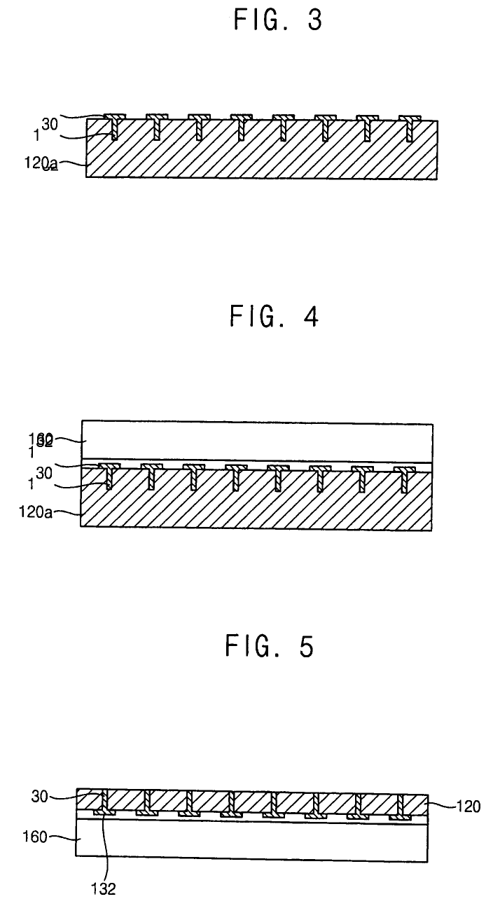

FIGS. 3 to 11 are cross-sectional views illustrating a method of manufacturing a stacked package in accordance with example embodiments of the present invention.

Referring to FIG. 3, a plurality of via holes is formed at a surface portion of a preliminary semiconductor chip 120a. In an example embodiment, the via holes may be formed at the surface portion of a scribe lane of the preliminary semiconductor chip 120a. Here, each of the via holes may have an opened upper end and a closed lower end. The via holes may be filled with the plugs 130. Here, each of the plugs 130 may have a head portion 132 protruded from the upper end of the via hole. Further, the plugs 130 may be electrically connected to bonding pads of the preliminary semiconductor chip 120a, respectively.

Referring to FIG. 4, a supporting member 160 is then attached to the surface of the preliminary semiconductor chip 120a. In an example embodiment, the supporting member 160 may include a dummy wafer.

Referring to FIG. 5, the preliminary semiconductor chip 120a is rotated by an angle of about 180° to place the supporting member 160 beneath the preliminary semiconductor chip 120a. The surface of the preliminary semiconductor chip 120a is then partially removed by a grinding process and/or a wet etching process to expose the upper end of the plugs 130. The supporting member 160 may be removed to complete the semiconductor chip 120 in which the plugs 130 having the exposed upper and lower ends are received. Here, the upper ends of the plugs 130 may protrude from the surface of the semiconductor chip 120. The method described with respect to FIGS. 3-5 may be repeated to form several semiconductor chips 120. Alternatively, several semiconductor chips 120 may be manufactured substantially simultaneously, in a wafer-level process for example, using the method described above with respect to FIGS. 3-5.

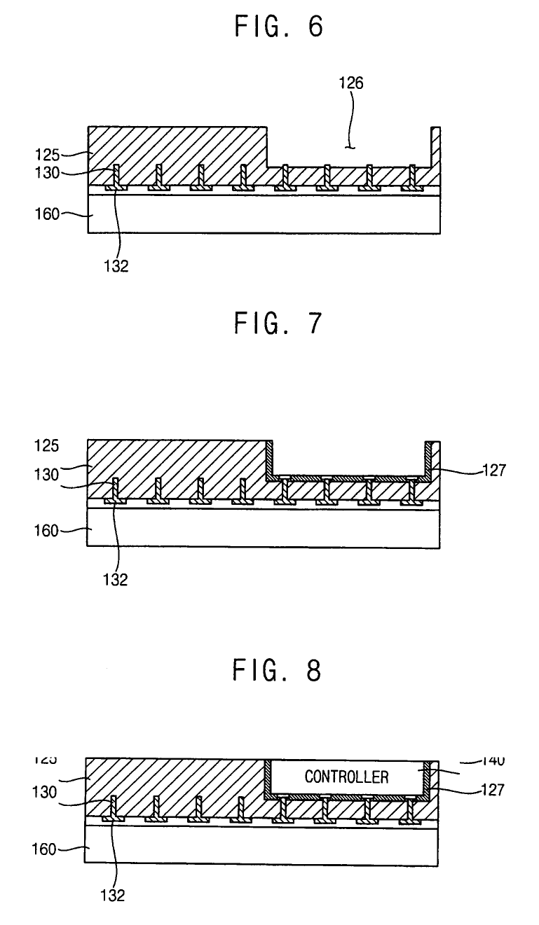

Referring to FIG. 6, the cavity 126 is then formed at any one of the semiconductor chips 120 to form the uppermost semiconductor chip 125. In an example embodiment, the uppermost semiconductor chip 125 may have a thickness greater than that of other semiconductor chips 120. Additionally, the upper ends of some of the plugs 130 are exposed through the bottom face of the cavity 126. As shown in FIG. 6, the head portions 132 of the plugs 130 are oriented downwards.

Referring to FIG. 7, the adhesive layer 127 is then formed on the inner face of the cavity 126. The upper ends of the plugs 130 may be exposed through the adhesive layer 127.

Referring to FIG. 8, the controller 140 is then loaded into the cavity 126 to bond the controller 140 to the inner face of the cavity 126 using the adhesive layer 127. In an example embodiment, the cavity 126 may have a depth substantially equal to or greater than the thickness of the controller 140. Thus, the controller 140 may not protrude from the surface of the uppermost semiconductor chip 125.

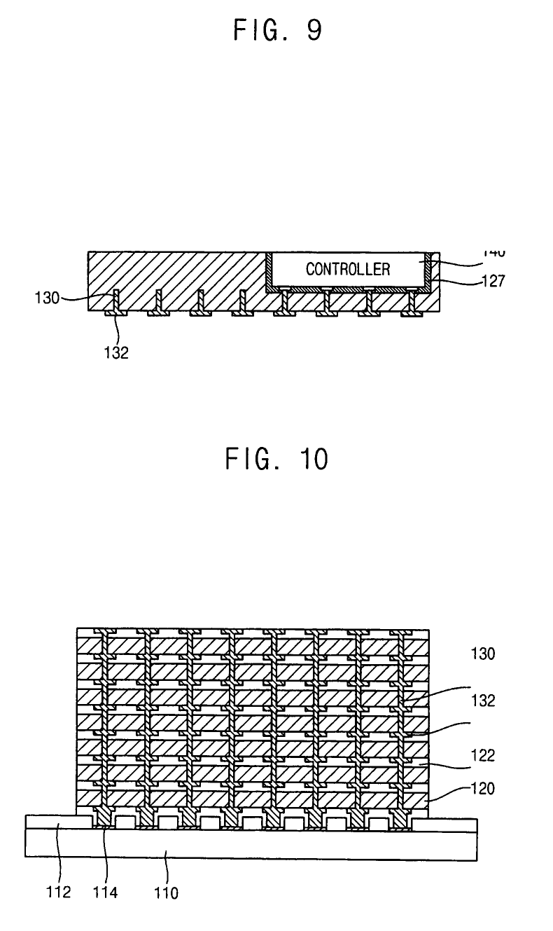

Referring to FIG. 9, the supporting member 160 is then removed from the uppermost semiconductor chip 125 to complete the uppermost semiconductor chip 125 in which the controller 140 is disposed.

Referring to FIG. 10, the semiconductor chips 120 are sequentially stacked on the PCB 110. Here, the plugs 130 are electrically coupled to each other. Further, the plugs 130 are electrically connected to the electrode pads 114 of the PCB 110, respectively. In an example embodiment, the adhesive layers 122 are interposed between the semiconductor chips 120. Thus, the semiconductor chips 120 are attached to each other using the adhesive layers 122.

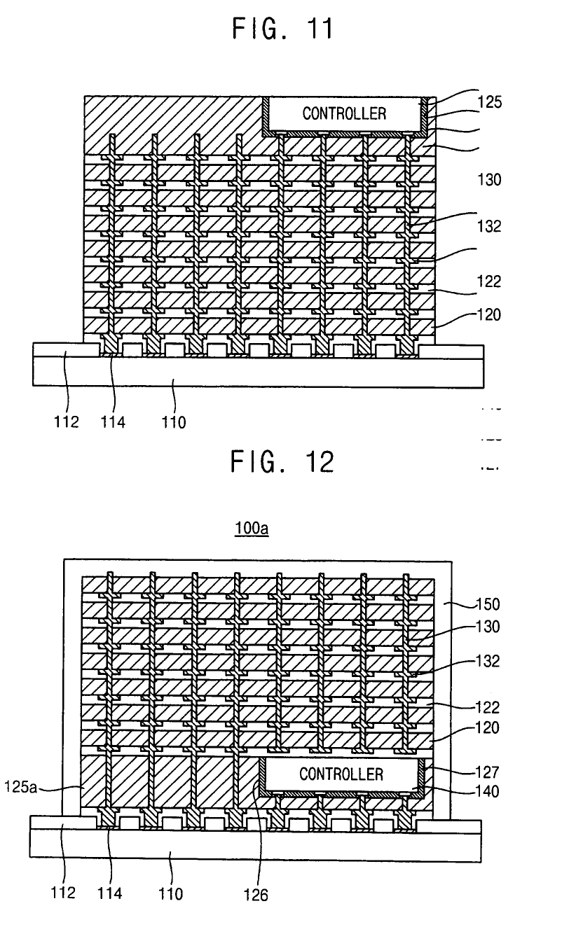

Referring to FIG. 11, the uppermost semiconductor chip 125 having the controller 140 is then stacked on the stacked semiconductor chips 120. The plugs 130 of the uppermost semiconductor chip 125 may be electrically connected to the plugs 130 of the semiconductor chip 120 beneath the uppermost semiconductor chip 125. Therefore, the controller 140 is electrically coupled to the electrode pads 114 of the PCB 110 through the plugs 130. Further, the adhesive layer 122 may be interposed between the uppermost semiconductor chip 125 and the semiconductor chip 120 beneath the uppermost semiconductor chip 125.

Referring again to FIG. 1, the protection member 150 is formed on the semiconductor chips 120, the uppermost semiconductor chip 125, including the controller 140, and the PCB 110 to complete the stacked package 100 illustrated in FIG. 1. The protection member 150 protects the semiconductor chips 120 and the uppermost semiconductor chip 125 having the controller 140 from external impacts.

According to example embodiments, the controller may be formed in the uppermost semiconductor chip by a separate process so that a mechanical impact generated in a process for bonding the controller may not be applied to the semiconductor chips. Further, a mechanical impact applied to the controller, which is generated in the process for forming the protection member, may be reduced so that the controller may not be damaged.

FIG. 12 is a cross-sectional view illustrating a stacked package in accordance with example embodiments of the present invention.

A stacked package 100a according to example embodiments of the present invention may include elements substantially the same as those of the stacked package 100 illustrated in FIG. 1 except for the position where the controller 140 is disposed. Thus, the same reference numerals refer to the same elements and any further illustrations with respect to the same elements are omitted herein for brevity.

Referring to FIG. 12, in the stacked package 100a, the controller 140 is disposed in a lowermost semiconductor chip 125a. The lowermost semiconductor chip 125a on the PCB 110 has the cavity 126. The controller 140 is attached to the inner face of the cavity 126 using the adhesive layer 127.

A method of manufacturing the stacked semiconductor package 100a may be substantially the same as that described with reference to FIGS. 3 to 11 except for the sequence where the lowermost semiconductor chip 125a, having the controller 140, is stacked on the PCB 110 and the semiconductor chips 120 are then stacked on the lowermost semiconductor chip 125a. Thus, any further illustrations with respect to the method of manufacturing this example embodiment are omitted herein for brevity.

FIG. 13 is a cross-sectional view illustrating a stacked package in accordance with example embodiments of the present invention.

A stacked package 100b in accordance with example embodiments of the present invention may include elements substantially the same as those of the stacked package 100 illustrated in FIG. 1 except for a position where the controller 140 is disposed. Thus, the same reference numerals refer to the same elements and any further illustrations with respect to the same elements are omitted herein for brevity.

Referring to FIG. 13, in the stacked package 100b, the controller 140 is disposed in any intermediate semiconductor chip 125b of the semiconductor chips 120 except for the uppermost semiconductor chip and the lowermost semiconductor chip. Thus, the intermediate semiconductor chip 125b has the cavity 126 for receiving the controller 140.

A method of manufacturing the stacked semiconductor package 100b may be substantially the same as that described with reference to FIGS. 3 to 11 except for a process for interposing the intermediate semiconductor chip 125b having the controller 140 between the semiconductor chips 120. Thus, any further illustrations with respect to the method of manufacturing this example embodiment are omitted herein for brevity.

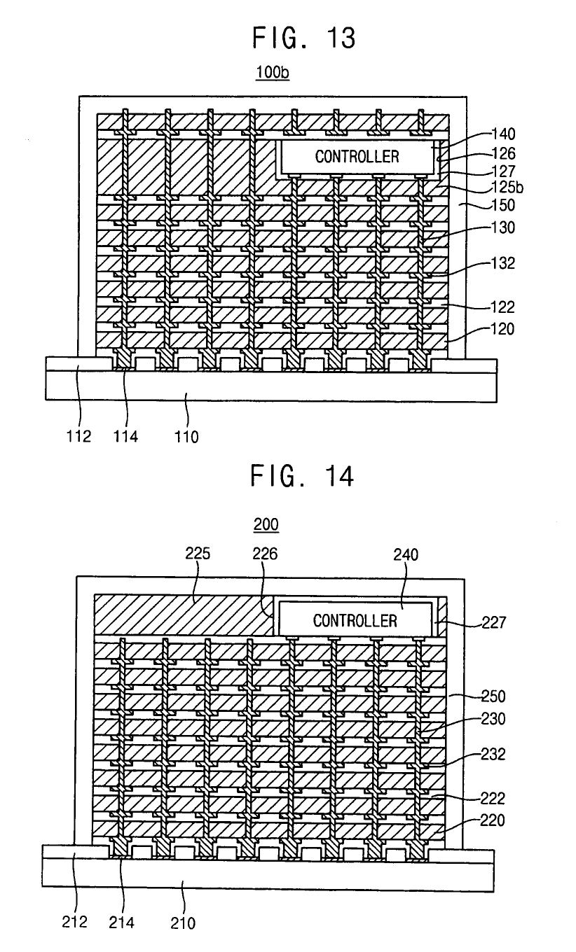

FIG. 14 is a cross-sectional view illustrating a stacked package in accordance with example embodiments of the present invention.

Referring to FIG. 14, a stacked package 200 of this example embodiment includes a PCB 210, a plurality of semiconductor chips 220, a dummy chip 225, plugs 230, a controller 240 and a protection member 250.

The PCB 210, the semiconductor chips 220, the plugs 230, the controller 240 and the protection member 250 are substantially the same as the PCB 110, the semiconductor chips 120, the plugs 130, the controller 140 and the protection member 150 illustrated in FIG. 1, respectively. Thus, any further illustrations with respect to the PCB 210, the semiconductor chips 220, the plugs 230, the controller 240 and the protection member 250 are omitted herein for brevity.

The dummy chip 225 is stacked on the surface of the uppermost one of the stacked semiconductor chips 220. The dummy chip 225 has a cavity 226 for exposing the plug 230 of the uppermost semiconductor chip among the semiconductor chips 220. An adhesive layer 227 is formed on an inner face of the cavity 226.

The controller 240 is attached to the inner face of the cavity 226 using the adhesive layer 227. Further, the controller 240 is electrically coupled to the exposed plugs 230. Thus, the controller 240 is electrically connected to electrode pads 214 of the PCB 210 through the plugs 230.

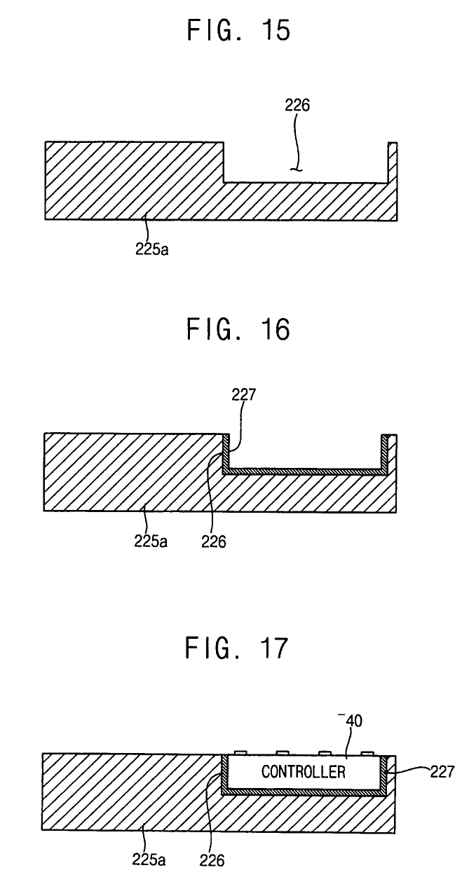

FIGS. 15 to 22 are cross-sectional views illustrating a method of manufacturing a stacked package in accordance with example embodiments of the present invention.

A process for forming the semiconductor chips 220 having the plugs 230 may be substantially the same as that described with reference to FIGS. 3 to 11. Thus, any further illustrations with respect to the process are omitted herein for brevity.

Referring to FIG. 15, the cavity 226 is formed at a surface portion of a preliminary dummy chip 225a.

Referring to FIG. 16, the adhesive layer 227 is then formed on the inner face of the cavity 226.

Referring to FIG. 17, the controller 240 is then loaded into the cavity 226 to bond the controller 240 to the inner face of the cavity 226 using the adhesive layer 227.

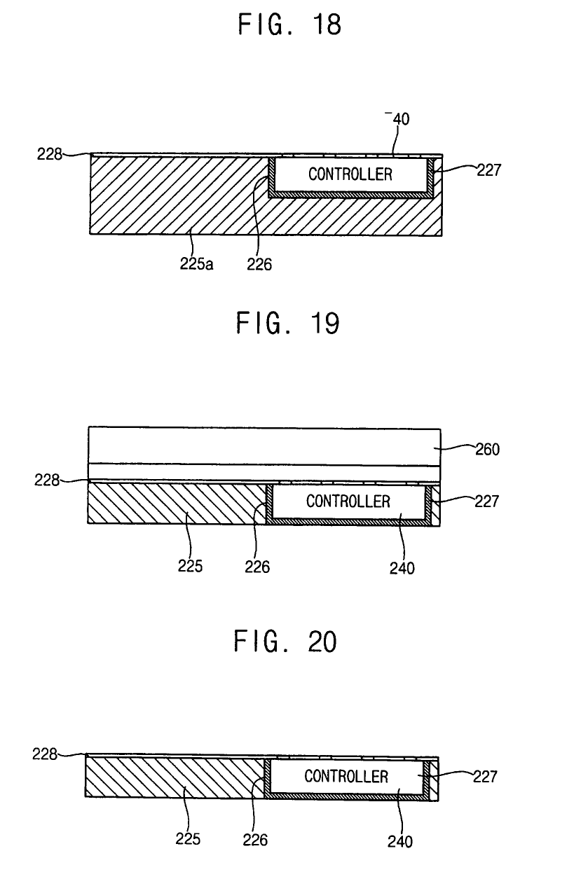

Referring to FIG. 18, the adhesive layer 228 is then formed on surfaces of the preliminary dummy chip 225a and the controller 240.

Referring to FIG. 19, a supporting member 260 is attached to the surface of the preliminary dummy chip 225a using the adhesive layer 228. The preliminary dummy chip 225a is then rotated by an angle of about 180° such that the supporting member 260 is oriented beneath the preliminary dummy chip 225a. The surface of the preliminary dummy chip 225a is then partially removed by a grinding process and/or a wet etching process.

Referring to FIG. 20, the supporting member 260 is removed to complete the dummy chip 225 in which the controller 240 is disposed.

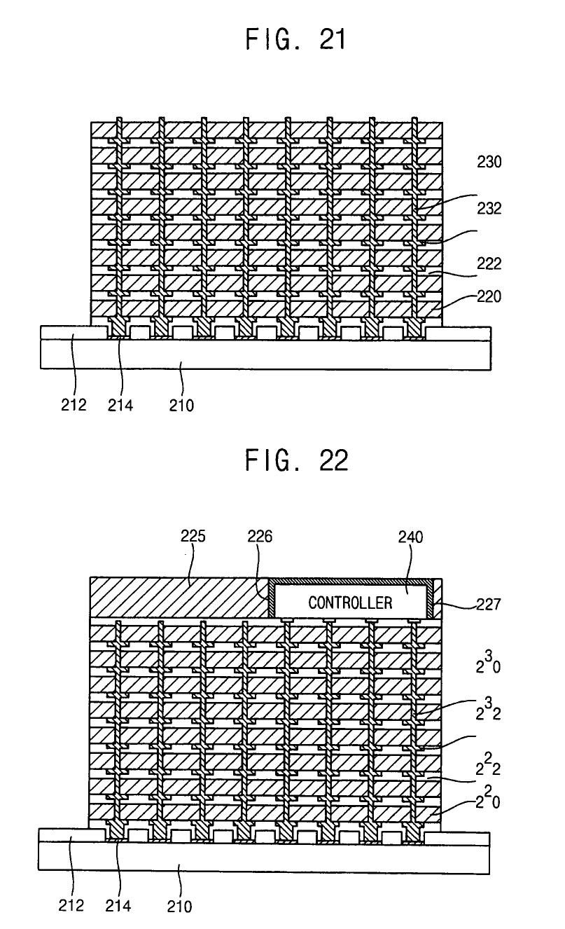

Referring to FIG. 21, the semiconductor chips 220 are sequentially stacked on the PCB 210. Here, the plugs 230 are electrically coupled to each other. Further, the plugs 230 are electrically connected to the electrode pads 214 of the PCB 210, respectively.

Referring to FIG. 22, the dummy chip 225 having the controller 240 is then stacked on the stacked semiconductor chips 220. Here, the controller 240 is electrically connected to the plugs 230 of the semiconductor chips 220. Therefore, the controller 240 is electrically coupled to the electrode pads 214 of the PCB 210 through the plugs 230.

Referring again to FIG. 14, the protection member 250 is formed on the semiconductor chips 220, the dummy chip 225 and the PCB 210 to complete the stacked package 200 of FIG. 14.

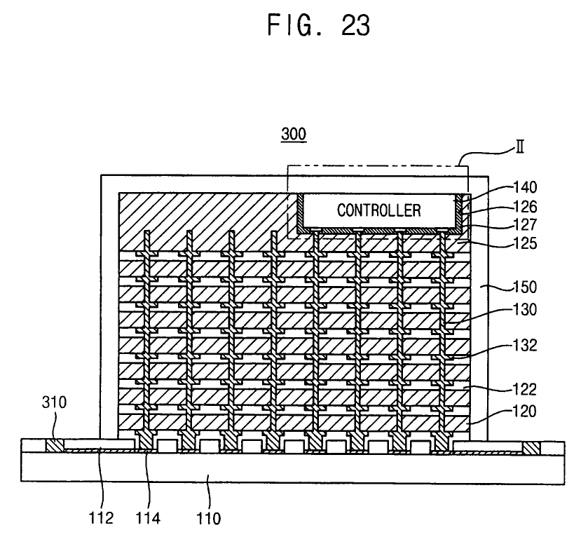

FIG. 23 is a cross-sectional view illustrating a memory card in accordance with example embodiments of the present invention.

Referring to FIG. 23, a memory card 300 of this example embodiment includes a stacked package 100 and at least one connector 310. Here, the stacked package 100 includes elements substantially the same as those of the stacked package 100 in FIG. 1. Thus, any further illustrations with respect to the stacked package 100 are omitted herein for brevity.

The PCB 110 has at least one circuit pattern 116 arranged on an upper face of the PCB 110. The circuit pattern 116 is electrically connected to the electrode pads 114. Thus, the circuit pattern is electrically connected to the semiconductor chips 120 through the electrode pads 114 and the plugs 130. The connector 310 is formed on the upper face of the PCB 110. The connector 310 is exposed by the stacked package 100. The connector 310 is connected to the electrode pads 114 through the circuit pattern 116. Thus, the connector 310 is electrically connected to the semiconductor chips 120 through the circuit pattern 116, the electrode pads 114 and the plugs 130.

According to this example embodiment, the controller may be built in the dummy chip by a separate process so that a mechanical impact generated in a process for bonding the controller may not be applied to the semiconductor chips. Further, a mechanical force applied to the controller, which is generated during the process of forming the protection member, may be reduced so that the controller may not be damaged.

According to example embodiments of the present invention, the controller may be built in the uppermost semiconductor chip, the lowermost semiconductor chip or the dummy chip by a separate process so that any mechanical impact generated in the process of bonding the controller may not be applied to the semiconductor chips.

Further, a mechanical impact applied to the controller, which is generated in a process for forming the protection member, may be reduced so that the controller may not be damaged.

A stacked package in accordance with one aspect of the present invention includes a printed circuit board (PCB), a plurality of semiconductor chips, plugs and a controller. The semiconductor chips are sequentially stacked on the PCB. The plugs electrically connect each of the semiconductor chips to the PCB. The controller is built in any one of the semiconductor chips. Further, the controller is electrically coupled to the plugs.

According to one example embodiment, the semiconductor chip in which the controller is built may have a cavity for receiving the controller. The plug may be exposed through the cavity. Further, an adhesive layer may be interposed between the inner face of the cavity and the controller.

According to another example embodiment, the controller may be built in an uppermost semiconductor chip, a lowermost semiconductor chip or any one of the intermediate semiconductor chips.

According to still another example embodiment, the plugs may be disposed in via holes vertically formed through the semiconductor chips. The plugs in the via holes may be electrically connected to each other. Further, each of the plugs may have a head portion protruded from the via hole. The head portion may make contact with the lower end of an adjacent plug.

Additionally, a protection member may be formed on the semiconductor chips so as to substantially surround the semiconductor chips.

In a method of manufacturing a stacked package in accordance with another aspect of the present invention, a plurality of semiconductor chips having plugs is prepared. A controller electrically coupled to the plugs is then formed in any one of the semiconductor chips. The semiconductor chips are sequentially stacked on a printed circuit board (PCB) to electrically connect the plugs to each other.

According to one example embodiment, preparing each of the semiconductor chips may include forming a via hole at the surface portion of a preliminary semiconductor chip, filling the via hole with the plug, and partially removing the bottom portion of the preliminary semiconductor chip to expose the plug.

According to another example embodiment, forming the controller may include forming a cavity at a surface portion of the semiconductor chip to expose the plug through the cavity, and bonding the controller on an inner face of the cavity so as to electrically connect the controller to the plug. Further, a supporting member may be attached to a bottom face of the semiconductor chip before forming the cavity. Also, an adhesive layer may be formed on the inner face of the cavity.

A stacked package in accordance with still another aspect of the present invention includes a printed circuit board (PCB), a plurality of semiconductor chips, a dummy chip, plugs and a controller. The semiconductor chips are sequentially stacked on the PCB. The dummy chip is stacked on the semiconductor chips. The plugs electrically connect each of the semiconductor chips to the PCB. The controller is disposed in the dummy chip. Further, the controller is electrically coupled to the plugs.

According to one example embodiment, the dummy chip may have a cavity for receiving the controller. The plug may be exposed through the cavity. Further, an adhesive layer may be interposed between an inner face of the cavity and the controller.

In a method of manufacturing a stacked package in accordance with yet another aspect of the present invention, a plurality of semiconductor chips having plugs is prepared. A controller is then formed in a dummy chip. The semiconductor chips and the dummy chip are sequentially stacked on a printed circuit board (PCB) to electrically connect the plugs to each other and the plugs to the controller.

According to one example embodiment, forming the controller may include forming a cavity at a surface portion of the dummy chip to expose the plug through the cavity, and bonding the controller on an inner face of the cavity to electrically connect the controller to the plug. Additionally, a supporting member may be attached to a bottom face of the dummy chip before forming the cavity. Furthermore, an adhesive layer may be formed on the inner face of the cavity.

According some embodiments of the present invention, the controller may be built in the semiconductor chip by a separate process so that a mechanical impact generated in a process for bonding the controller may not be applied to the semiconductor chips. Further, a mechanical impact generated in a process for forming the protection member may not be applied to the controller.

The foregoing is illustrative of the present invention and is not to be construed as limiting thereof. Although a few example embodiments of the present invention have been described, those skilled in the art will appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A stacked package comprising:
a printed circuit board (PCB);
a plurality of semiconductor chips sequentially stacked on the PCB;
plugs for electrically connecting the semiconductor chips to the PCB; and
a controller disposed in any one of the semiconductor chips and electrically connected to the plugs.

2. The stacked package of claim 1, wherein the semiconductor chip having the controller has a cavity for receiving the controller, and the plugs are exposed through the cavity.

3. The stacked package of claim 2, further comprising an adhesive layer interposed between an inner face of the cavity and the controller.

4. The stacked package of claim 1, wherein the controller is disposed in an uppermost semiconductor chip, a lowermost semiconductor chip or any one of the intermediate semiconductor chips.

5. The stacked package of claim 1, wherein the plugs are disposed in via holes vertically formed through the semiconductor chips to be electrically connected to each other.

6. The stacked package of claim 5, wherein each of the plugs has a head portion protruded from the via holes, and the head portion makes contact with a lower end of an adjacent plug.

7. The stacked package of claim 1, further comprising a protection member substantially surrounding the semiconductor chips.

8. A stacked package comprising:
a printed circuit board (PCB);
a plurality of semiconductor chips sequentially stacked on the PCB;
a dummy chip stacked on the semiconductor chips;
plugs for electrically connecting the semiconductor chips to the PCB; and
a controller disposed in the dummy chip and electrically connected to the plugs.

9. The stacked package of claim 8, wherein the dummy chip has a cavity for receiving the controller, and the plugs are exposed through the cavity.

10. The stacked package of claim 9, further comprising an adhesive layer interposed between an inner face of the cavity and the controller.

11. The stacked package of claim 8, further comprising a protection member substantially surrounding the semiconductor chips and the dummy chip.

12. A method of manufacturing a stacked package, comprising:
preparing a plurality of semiconductor chips having plugs;
building a controller in any one of the semiconductor chips, the controller being electrically connected to the plugs; and
sequentially stacking the semiconductor chips on a printed circuit board (PCB), the plugs being electrically connected to each other.

13. The method of claim 12, wherein preparing the semiconductor chips comprises:
forming via holes at a surface portion of a preliminary semiconductor chip;
filling the via holes with the plugs; and
partially removing a bottom portion of the preliminary semiconductor chips to expose the plugs.

14. The method of claim 12, wherein building the controller in the semiconductor chip comprises:
forming a cavity at a surface portion of the semiconductor chip to expose the plugs through the cavity; and
bonding the controller to an inner face of the cavity, the controller being electrically connected to the plugs.

15. The method of claim 14, further comprising attaching a supporting member on a bottom face of the semiconductor chip before forming the cavity.

16. The method of claim 14, further comprising forming an adhesive layer on the inner face of the cavity.

17. The method of claim 12, wherein the controller is built in an uppermost semiconductor chip, a lowermost semiconductor chip or any one of the semiconductor chips except for the uppermost semiconductor chip and the lowermost semiconductor chip.

18. The method of claim 12, further comprising surrounding the semiconductor chips with a protection member.

19. A method of manufacturing a stacked package, comprising:
preparing a plurality of semiconductor chips having plugs;
building a controller in a dummy chip; and
sequentially stacking the semiconductor chips and the dummy chip on a printed circuit board (PCB), the plugs being electrically connected to each other and the plugs and the controller being electrically connected to each other.

20. The method of claim 19, wherein building the controller in the dummy chip comprises:
forming a cavity at a surface portion of the dummy chip to expose the plugs through the cavity; and
bonding the controller to an inner face of the cavity, the controller being electrically connected to the plugs.

21. The method of claim 20, further comprising attaching a supporting member on a bottom face of the dummy chip before forming the cavity.

22. The method of claim 20, further comprising forming an adhesive layer on the inner face of the cavity.

23. The method of claim 19, further comprising surrounding the semiconductor chips and the dummy chip with a protection member.

24. A memory card comprising:
a printed circuit board (PCB) having a circuit pattern;
a plurality of semiconductor chips sequentially stacked on the PCB;
plugs for electrically connecting the semiconductor chips to the PCB;
a controller disposed in any one of the semiconductor chips and electrically connected to the plugs; and
a connector formed on the PCB and electrically connected to the semiconductor chips through the circuit pattern.
